(19) United States
(12) Patent Application Publication
(10) Pub. No.: US 2021/0138605 A1
(43) Pub. Date: May 13, 2021

(54) POLISHING PAD, PREPARATION METHOD THEREOF, AND PREPARATION METHOD OF SEMICONDUCTOR DEVICE USING SAME

(71) Applicant: SKC CO., LTD., Gyeonggi-do (KR)

(72) Inventors: Hyeyoung HEO, Gyeonggi-do (KR); Jong Wook YUN, Gyeonggi-do (KR); Myung-Ok KYUN, Gyeonggi-do (KR); Jang Won SEO, Gyeonggi-do (KR)

(21) Appl. No.: 17/077,216

(22) Filed: Oct. 22, 2020

(30) Foreign Application Priority Data
Nov. 11, 2019 (KR) 10-2019-0143412

(51) Int. Cl. B24B 37/26; H01L 21/304; B24B 37/24

(52) U.S. Cl. CPC B24B 37/26; B24B 37/24; H01L 21/304

(57) ABSTRACT

The embodiments provide a polishing pad, a process for preparing the same, and a process for preparing a semiconductor device using the same. In the polishing pad according to an embodiment, the average value of the modulus of the pore region and that of the non-pore region is adjusted to 0.5 GPa to 1.6 GPa, whereby it is possible to achieve an excellent life span, to improve the scratches and surface defects appearing on the surface of a semiconductor substrate, and to further enhance the polishing rate.

### TECHNICAL FIELD

Embodiments relate to a polishing pad for use in a chemical mechanical planarization (CMP) process of semiconductors, a process for preparing the same, and a process for preparing a semiconductor device using the same.

### BACKGROUND ART

The chemical mechanical planarization (CMP) process in a process for preparing semiconductors refers to a step in which a semiconductor substrate such as a wafer is fixed to a head and in contact with the surface of a polishing pad mounted on a platen, and the wafer is then chemically treated by supplying a slurry while the platen and the head are relatively moved, to thereby mechanically planarize the irregularities on the semiconductor substrate.

A polishing pad is an essential member that plays an important role in such a CMP process. In general, a polishing pad comprises a polishing layer composed of a polyurethane-based resin and a support layer, and the polishing layer has, on its surface, grooves for a large flow of a slurry and pores for supporting a fine flow thereof. The pores in a polishing layer may be formed by using a solid phase foaming agent having a fine hollow structure, a liquid phase foaming agent using a volatile liquid, a gas phase foaming agent such as an inert gas, or the like, or by generating a gas by a chemical reaction.

Since the polishing layer comprising pores directly interacts with the surface of a semiconductor substrate during the CMP process, it affects the processing quality of the surface of the semiconductor substrate. In particular, the polishing rate and the occurrence of defects such as scratches during the CMP process may sensitively vary with the components and physical properties of the polishing layer, as well as the shape and physical properties of pores. In addition, as the occurrence of defects such as surface scratches increases, the polishing rate may be decreased, which deteriorates the quality of the semiconductor substrate.

Thus, there has been a continuing demand for research on the enhancement of the polishing rate by minimizing scratches and surface defects occurring on the semiconductor substrate during the CMP process.

### PRIOR ART DOCUMENT

### Patent Document

(Patent Document 1) Korean Patent No. 10-1608901

### DETAILED DESCRIPTION OF THE INVENTION

### Technical Problem

The present invention aims to solve the above problems of the prior art.

The technical problem to be solved by the present invention is to provide a polishing pad in which the modulus of the pore region and that of the non-pore region are controlled, whereby it is possible to improve the scratches and surface defects appearing on the surface of a semiconductor substrate and to further enhance the polishing rate, and a process for preparing the same.

In addition, it is aimed to provide a process for preparing a semiconductor device useful for a layer to be polished of both an oxide layer and a tungsten layer using the polishing pad.

### Solution to the Problem

In order to achieve the above object, an embodiment provides a polishing pad, which comprises a polishing layer comprising a pore region comprising a plurality of pores and a non-pore region devoid of pores, wherein an average value of the modulus of a pore region and that of the non-pore region according to the following Formula 1 is 0.5 GPa to 1.6 GPa:

(modulus of the pore region+modulus of the non-pore region)/2. [Equation 1]

Another embodiment provides a process for preparing a polishing pad, which comprises mixing a urethane-based prepolymer, a curing agent, and a foaming agent to prepare a raw material mixture; and injecting the raw material mixture into a mold to cure it, wherein the polishing pad comprises a polishing layer comprising a pore region comprising a plurality of pores and a non-pore region devoid of pores, and an average value of a modulus of the pore region and that of the non-pore region according to the above Formula 1 is 0.5 GN to 1.6 GPa.

Still another embodiment provides a process for preparing a semiconductor device, which comprises providing a polishing pad; disposing an object to be polished on the polishing pad; and rotating the object to be polished relative to the polishing pad to polish the object to be polished, wherein the polishing pad comprises a polishing layer comprising a pore region comprising a plurality of pores and a non-pore region devoid of pores, and an average value of a modulus of the pore region and that of the non-pore region according to the above Formula 1 is 0.5 GPa to 1.6 GPa.

### Advantageous Effects of the Invention

In the polishing pad according to the embodiment, the modulus of the pore region and that of the non-pore region are controlled, whereby it is possible to achieve an excellent life span of the polishing pad, to improve the scratches and surface defects appearing on the surface of a semiconductor substrate, and to further enhance the polishing rate.

### BRIEF DESCRIPTION OF THE DRAWINGS

FIG. 1 shows the top view of the polishing layer of a polishing pad according to an embodiment.

FIG. 2 shows a cross-section of the polishing layer of a polishing pad according to an embodiment.

FIG. 3 shows a process of polishing an object to be polished using a polishing pad according to an embodiment.

FIG. 4 schematically illustrates a process for preparing a semiconductor device according to an embodiment.

### BEST MODE FOR CARRYING OUT THE INVENTION

In the description of the following embodiments, in the case where each layer or pad is mentioned to be formed “on” or “under” another layer or pad, it means not only that one element is “directly” formed on or under another element, but also that one element is “indirectly” formed on or under another element with other element(s) interposed between them.

In addition, the term on or under with respect to each element may be referenced to the drawings. For the sake of description, the sizes of individual elements in the appended drawings may be exaggeratingly depicted and do not indicate the actual sizes.

In addition, all numerical ranges related to the physical properties, dimensions, and the like of a component used herein are to be understood as being modified by the term “about,” unless otherwise indicated.

[Polishing Pad]

The polishing pad according to an embodiment comprises a polishing layer comprising a pore region comprising a plurality of pores and a non-pore region devoid of pores, wherein an average value of the modulus of a pore region and that of the non-pore region according to the following Formula 1 is 0.5 GPa to 1.6 GPa:

(modulus of the pore region+modulus of the non-pore region)/2. [Equation 1]

According to an embodiment of the present invention, the modulus of the pore region and that of the non-pore region are adjusted to control their average value, whereby it is possible to achieve an excellent life span of the polishing pad, to improve the scratches and surface defects appearing on the surface of a semiconductor substrate during the CMP process, and to further enhance the polishing rate.

Polishing Layer

According to an embodiment of the present invention, the polishing pad comprises a polishing layer comprising a pore region comprising a plurality of pores and a non-pore region devoid of pores.

Specifically, as shown in FIGS. 1 to 3, the polishing layer (100) comprises a pore region (125) comprising a plurality of pores (121, 122, and 130) and a non-pore region (110) devoid of pores.

A number average diameter of the plurality of pores may be about 10 μm to 60 μm. In more detail, the number average diameter of the pores may be about 12 μm to about 50 μm. In more detail, the number average diameter of the pores may be about 12 μm to about 40 μm. The number average diameter of the pores may be defined as an average value obtained by dividing the sum of the diameters of the plurality of pores by the number of the pores.

The polishing layer may comprise a closed pore (130) and open pores (121, 122). The closed pores are disposed inside the polishing layer.

The open pores are disposed on the upper surface of the polishing layer and are exposed to the outside. The open pores may comprise a first open pore (121) and a second open pore (122) disposed on the upper surface of the polishing layer. The first open pore and the second open pore may be adjacent to each other and spaced from each other.

The average diameter (D) of the open pores may be about 20 μm to about 40 μm, and the average depth (H) of the open pores may be about 20 μm to about 40 μm.

The non-pore region (110) corresponds to the region between the first open pore (121) and the second open pore (122). That is, the non-pore region may be the flat surface between the first open pore and the second open pore. In more detail, the non-pore region may be the region other than the open pores.

As shown in FIG. 3, the polishing layer may be in direct contact with an object to be polished such as a semiconductor substrate (200). That is, the polishing layer is in direct contact with the object to be polished such as a semiconductor substrate and may directly participate in the polishing of the object to be polished.

According to an embodiment of the present invention, the average value of the modulus of the pore region (125) and that of the non-pore region (110) may be 0,5 GPa to 1.6 GPa, 0.6 GPa to 1.6 GPa, 0.6 GPa to 1.5 GPa, 0.9 GPa to 1.4 GPa, or 1.0 GPa to 1.35 GPa. Here, the average value of the modulus of the pore region and that of the non-pore region may be obtained by applying a force of 100 μN to the pore region and the non-pore region, respectively, with a nano indenter (TI-950 of Bruker), plotting the strain versus stress after the force is released, calculating the modulus as the slope, and producing an average value thereof.

If the average value of the modulus of the pore region (125) and that of the non-porous region (110) is within the above range, it is possible to enhance the polishing rate and within-wafer non-uniformity for oxides and tungsten and to significantly reduce the scratches appearing on the surface of a semiconductor substrate.

On the other hand, if the average value of the modulus of the pore region and that of the non-porous region is less than the above range, the life span of the polishing pad may be reduced, the polishing rate for tungsten may be excessively increased, and the within-wafer non-uniformity may be poor. In addition, if the average value of the modulus of the pore region and that of the non-porous region exceeds the above range, the polishing rate for oxides may be excessively increased, the within-wafer non-uniformity may be poor, and the scratches appearing on the surface of a semiconductor substrate may be significantly increased.

The modulus of the pore region may be 0.5 GPa to 2.0 GPa, 0.8 GPa to 1.8 GPa, 0.9 GPa to 1.6 GPa, or 0.98 GPa to 1.6 GPa.

In addition, the modulus of the non-pore region may be 0.5 GPa to 2.0 GPa 0.8 GPa to 1.6 GPa, 0.9 GPa to 1.5 GPa, or 1.05 GPa to 1.3 GPa.

In addition, an absolute value of the difference in modulus between the pore region and the non-pore region is less than 1 GPa, 0.02 GPa to 0.8 GPa, 0.02 GPa to 0.6 GPa, 0.02 GPa to 0.55 GPa, 0.03 GPa to 0.53 GPa, or 0.03 GPa to 0.5 GPa. As the difference in modulus between the pore region and the non-pore region decreases, it is possible to enhance the polishing rate and to reduce the scratches appearing on the surface of a semiconductor substrate.

If any of the modulus of the pore region and the modulus of the non-pore region is excessively increased or decreased, thereby increasing the difference, the scratches appearing on the surface of a semiconductor substrate may be remarkably increased, and the polishing rate may be adversely affected.

In addition, the pores may be contained in the number of 100 to 1,500, 300 to 1,400, 500 to 1,300, or 500 to 1,250 per 1 mm² of the polishing pad.

In addition, the total area of the pores may be 30% to 60%, 35% to 50%, or 40% to 55%, based on the total area of the polishing pad.

The polishing layer may have an area ratio of the pore region and the non-pore region per unit area of 1:0.6 to 2.4, 1:0.8 to 1.8, or 1:0.8 to 1.5.

Meanwhile, the polishing layer comprises a cured material of a composition comprising a urethane-based prepolymer, a curing agent, and a foaming agent. Each component contained in the composition will be described below in detail.

Urethane-Based Prepolymer

A prepolymer generally refers to a polymer having a relatively low molecular weight wherein the degree of polymerization is adjusted to an intermediate level so as to conveniently mold a molded article to be finally produced in the process of preparing the same. A prepolymer may be molded by itself or after a reaction with another polymerizable compound. For example, a prepolymer may be prepared by reacting an isocyanate compound with a polyol.

The isocyanate compound used in the preparation of the urethane-based prepolymer may be an aromatic diisocyanate, an aliphatic diisocyanate, an alicyclic diisocyanate, or a mixture thereof. For example, it may be at least one isocyanate selected from the group consisting of toluene diisocyanate (TDI), naphthalene-1,5-diisocyanate, p-phenylene diisocyanate, tolidine diisocyanate, 4,4′-diphenylmethane diisocyanate, hexamethylene diisocyanate, dicyclohexylmethane diisocyanate, and isophorone diisocyanate.

For example, the polyol that may be used in the preparation of the urethane-based prepolymer may be at least one polyol selected from the group consisting of a polyether polyol, a polyester polyol, a polycarbonate polyol, and an acryl polyol. The polyol may have a weight average molecular weight (Mw) of 300 to 3,000 g/mole.

The urethane-based prepolymer may have a weight average molecular weight of 500 to 3,000 g/mole. Specifically, the urethane-based prepolymer may have a weight average molecular weight (Mw) of 600 to 2,000 g/mole or 800 to 1,000 g/mole.

As an example, the urethane-based prepolymer may be a polymer obtained by polymerization of toluene diisocyanate as an isocyanate compound and polytetramethylene ether glycol as a polyol and having a weight average molecular weight (Mw) of 500 to 3,000 g/mole.

In addition, the urethane-based prepolymer may be obtained by using a mixture of toluene diisocyanate and an aliphatic diisocyanate or an alicyclic diisocyanate. For example, it may be obtained by using toluene diisocyanate (TDI) and dicyclohexylmethane diisocyanate (H12MDI) as an isocyanate compound and polytetramethylene ether glycol (PTMEG) and diethylene glycol (DEG) as a polyol.

The urethane-based prepolymer has a content (NCO %) of isocyanate end groups of 8% by weight to 9.4% by weight, specifically 8.8% by weight to 9.4% by weight, more specifically 9% by weight to 9.4% by weight.

If the NCO % satisfies the above range, the modulus of the pore region and that of the non-pore region as desired in the present invention may be achieved.

If the NCO % is less than the above range, the hardness and modulus of the polishing pad may be decreased, so that the polishing rate for a wafer film, which is a semiconductor substrate, may be decreased, the within-wafer non-uniformity may be poor, and there may be a problem that the life span of the polishing pad may be reduced since the cutting force of the polishing pad may be increased. On the other hand, if the NCO % exceeds the above range, the average value of the modulus of the pore region and that of the non-pore region is excessively increased, so that the polishing rate for oxides may be excessively increased, the within-wafer non-uniformity may be poor, and the scratches on the surface of a semiconductor substrate may be increased.

Curing Agent

The curing agent may be at least one of an amine compound and an alcohol compound. Specifically, the curing agent may be at least one compound selected from the group consisting of an aromatic amine, an aliphatic amine, an aromatic alcohol, and an aliphatic alcohol.

For example, the curing agent may comprise at least one selected from a group consisting of 4,4′-methylenebis(2-chloroaniline) (MOCA), diethyltoluenediamine (DETDA), diaminodiphenylmethane, diaminodiphenyl sulphone, m-xylylenediamine, isophoronediamine, ethylenediamine, diethylenetriamine, triethylenetetramine, polypropylenediamine, polypropylenetriamine, and bis(4-amino-3-chlorophenyl)methane.

The content of the curing agent may be 18 parts by weight to 27 parts by weight, specifically 19 parts by weight to 26 parts by weight, more specifically 20 parts by weight to 25 parts by weight, based on 100 parts by weight of the urethane-based prepolymer.

If the content of the curing agent satisfies the above range, the modulus of the pore region and that of the non-pore region as desired in the present invention may be achieved.

If the content of the curing agent is less than 18 parts by weight, the average value of the modulus of the pore region and that of the non-pore region may be excessively decreased. In this case, the life span of the polishing pad may be reduced. In addition, if the content of the curing agent exceeds 27 parts by weight, the average value of the modulus of the pore region and that of the non-pore region is increased, so that the polishing rate for oxides may be excessively increased, the within-wafer non-uniformity may be poor, thereby adversely affecting the polishing performance, and the scratches on the surface of a semiconductor substrate may be increased.

Foaming Agent

According to an embodiment of the present invention, the foaming agent may comprise a solid phase foaming agent, a gas phase foaming agent, or both.

Solid Phase Foaming Agent

According to an embodiment of the present invention, the composition may comprise a solid phase foaming agent as a foaming agent.

The solid phase foaming agent is thermally expanded microcapsules and may have a structure of micro-balloons having an average particle diameter of 5 to 200 μm. Specifically, the solid phase foaming agent may have an average particle diameter of 21 μm to 50 μm. More specifically, the solid phase foaming agent may have an average particle diameter of 25 μm to 45 μm. In addition, the thermally expanded microcapsules may be obtained by thermally expanding thermally expandable microcapsules.

The thermally expandable microcapsule may comprise a shell comprising a thermoplastic resin; and a foaming agent encapsulated inside the shell. The thermoplastic resin may be at least one selected from the group consisting of a vinylidene chloride-based copolymer, an acrylonitrile-based copolymer, a methacrylonitrile-based copolymer, and an acrylic-based copolymer. Further, the foaming agent encapsulated in the inside may be at least one selected from the group consisting of hydrocarbons having 1 to 7 carbon atoms. Specifically, the foaming agent encapsulated in the inside may be selected from the group consisting of a low molecular weight hydrocarbon such as ethane, ethylene, propane, propene, n-butane, isobutane, n-butene, isobutene, n-pentane, isopentane, neopentane, n-hexane, heptane, petroleum ether, and the like; a chlorofluorohydrocarbon such as trichlorofluoromethane (CCl₃F), dichlorodifluoromethane (CCl₂F₂), chlorotrifluoromethane (CClF₃), tetrafluoroethylene (CClF₂—CClF₂), and the like; and a tetraalkylsilane such as tetramethylsilane, trimethylethylsilane, trimethylisopropylsilane, trimethyl-n-propylsilane, and the like.

The solid phase foaming agent may be employed in an amount of 0.5 to 10 parts by weight, 1 to 3 parts by weight, 1.3 to 2.7 parts by weight, or 1.3 to 2.6 parts by weight, based on 100 parts by weight of the urethane-based prepolymer.

Gas Phase Foaming Agent

According to an embodiment of the present invention, the composition may comprise a gas phase foaming agent as a foaming agent.

The gas phase foaming agent may comprise an inert gas. The gas phase foaming agent may be fed when the urethane-based prepolymer, the curing agent, the solid phase foaming agent, a reaction rate controlling agent, and a surfactant are mixed and reacted, to thereby form pores. The kind of the inert gas is not particularly limited as long as it is a gas that does not participate in the reaction between the prepolymer and the curing agent. For example, the inert gas may be at least one selected from the group consisting of nitrogen gas (N₂), argon gas (Ar), and helium gas (He). Specifically, the inert gas may be nitrogen gas (N₂) or argon gas (Ar).

The inert gas may be fed in a volume of 5% to 30% based on the total volume of the raw material mixture, for example, the total volume of the urethane-based prepolymer, the curing agent, the solid phase foaming agent, the reaction rate controlling agent, and/or the surfactant. Specifically, the inert gas may be fed in a volume of 5% by volume to 30% by volume, 6% by volume to 25% by volume, 5% by volume to 20% by volume, or 8% by volume to 25% by volume, based on the total volume of the urethane-based prepolymer, the curing agent, the solid phase foaming agent, the reaction rate controlling agent, and/or the surfactant. In addition, if the raw material mixture does not contain a solid phase foaming agent, the inert gas may be calculated based on the total volume of the urethane-based prepolymer, the curing agent, the reaction rate controlling agent, and the surfactant, excluding the solid phase foaming agent.

Silicon (Si) Element

According to an embodiment of the present invention, the polishing layer may comprise a silicon (Si) element. The silicon (Si) element may be derived from various sources. For example, the silicon (Si) element may be derived from a foaming agent and various additives used in the preparation of a polishing layer. In such event, the additives may comprise, for example, a surfactant.

The content of a silicon (Si) element in the polishing layer may be designed in an appropriate range by using only one of a foaming agent and an additive and adjusting the type and content thereof or may be designed in an appropriate range by using both of a foaming agent and an additive and adjusting the type and content thereof.

The content of a silicon (Si) element in the polishing layer may be 5 ppm to 500 ppm, 5 ppm to 400 ppm, 8 ppm to 300 ppm, 220 ppm to 400 ppm, or 5 ppm to 180 ppm. In such event, the content of a silicon (Si) element in the polishing layer may be measured by inductively coupled plasma atomic emission spectrometer (ICP) analysis

The content of a silicon (Si) element in the polishing layer may affect the modulus of the pore region and that of the non-pore region. If the content of a silicon (Si) element satisfies the above range, the modulus of the pore region and that of the non-pore region as desired in the present invention may be achieved.

If the content of a silicon (Si) element exceeds 500 ppm, the average value of the modulus of the pore region and that of the non-pore region may be excessively increased. In this case, the scratches on the surface of a semiconductor substrate may he significantly increased.

According to an embodiment of the present invention, in the composition comprising a urethane-based prepolymer, a curing agent, and a foaming agent, the content of the curing agent is 19 parts by weight to 26 parts by weight based on 100 parts by weight of the urethane-based prepolymer, the content of a silicon (Si) element in the polishing layer is 5 ppm to 400 ppm, and the urethane-based prepolymer may have a content (NCO %) of isocyanate end groups of 9% to 9.4% by weight.

Surfactant

According to an embodiment of the present invention, the composition may further comprise a surfactant.

The surfactant may comprise a silicone-based surfactant. It may act to prevent the pores to be formed from overlapping and coalescing with each other. The kind of the surfactant is not particularly limited as long as it is commonly used in the production of a polishing pad. Examples of the commercially available silicone-based surfactant include B8749LF, B8736LF2, and B8734LF2 manufactured by Evonik.

The surfactant may be employed in an amount of 0.2 part by weight to 2 parts by weight based on 100 parts by weight of the urethane-based prepolymer. Specifically, the surfactant may be employed in an amount of 0.2 part by weight to 1.9 parts by weight, 0.2 part by weight to 1.8 parts by weight, 0.2 part by weight to 1.7 parts by weight, 0.2 part by weight to 1.6 parts by weight, 0.2 part by weight to 1.5 parts, or 0.5 part by weight to 1.5 parts by weight, based on 100 parts by weight of the urethane-based prepolymer. If the amount of the surfactant is within the above range, pores derived from the gas phase foaming agent can be stably formed and maintained in the mold.

Reaction Rate Controlling Agent

According to an embodiment of the present invention, the composition may comprise a reaction rate controlling agent.

The reaction rate controlling agent may be a reaction promoter or a reaction retarder. Specifically, the reaction rate controlling agent may be a reaction promoter. For example, it may be at least one reaction promoter selected from the group consisting of a tertiary amine-based compound and an organometallic compound.

Specifically, the reaction rate controlling agent may comprise at least one selected from the group consisting of triethylenediamine, dimethylethanolamine, tetramethylbutanediamine, 2-methyl-triethylenediamine, dimethylcyclohexylamine, triethylamine, triisopropanolamine, 1,4-diazabicyclo(2,2,2)octane, bis(2-methyaminoethyl) ether, trimethylaminoethylethanolamine, N,N,N,N,N″-pentamethyldiethylenetriamine, dimethylaminoethylamine, dimethylaminopropylamine, benzyldimethylamine, N-ethylmorpholine, N,N-dimethylaminoethylmorpholine, N,N-dimethylcycloamine, 2-methyl-2-azanorbornane, dibutyltin dilaurate, stannous octoate, dibutyltin diacetate, dioctyltin diacetate, dibutyltin maleate, dibutyltin di-2-ethylhexanoate, and dibutyltin dimercaptide. Specifically, the reaction rate controlling agent may comprise at least one selected from the group consisting of benzyldimethylamine, N,N-dimethylcyclohexylamine, and triethylamine.

The reaction rate controlling agent may be employed in an amount of 0.05 parts by weight to 2 parts by weight based on 100 parts by weight of the urethane-based prepolymer. Specifically, the reaction rate controlling agent may be employed in an amount of 0.05 part by weight to 1.8 parts by weight, 0.05 part by weight to 1.7 parts by weight, 0.05 part by weight to 1.6 parts by weight, 0.1 part by weight to 1.5 parts by weight, 0.1 part by weight to 0.3 part by weight, 0.2 part by weight to 1.8 parts by weight. 0.2 part by weight to 1.7 parts by weight, 0.2 part by weight to 1.6 parts by weight, 0.2 part by weight to 1.5 parts by weight, or 0.5 part by weight to 1 part by weight, based on 100 parts by weight of the urethane-based prepolymer. If the reaction rate controlling agent is employed in an amount within the above range, the reaction rate (i.e., the time for solidification of the mixture) of the mixture (e.g., the urethane-based prepolymer, the curing agent, the solid phase foaming agent, the reaction rate controlling agent, and the silicone-based surfactant) is properly controlled, whereby pores of a desired size can be formed.

Hereinafter, the process for preparing a polishing pad according to an embodiment of the present invention will be described in detail.

[Process for Preparing a Polishing Pad]

The process for preparing a polishing pad according to an embodiment comprises mixing a urethane-based prepolymer, a curing agent, and a foaming agent to prepare a raw material mixture; and injecting the raw material mixture into a mold to cure it, wherein the polishing pad comprises a polishing layer comprising a pore region comprising a plurality of pores and a non-pore region devoid of pores, and the average value of the modulus of the pore region and that of the non-pore region according to the above Formula 1 is 0.5 GPa to 1.6 GPa.

In the polishing pad according to an embodiment of the present invention, the component of the composition comprising the urethane-based prepolymer, the curing agent, and the foaming agent is optimized, so that the properties of the CMP pad as desired in the present invention, as well as the modulus of the pore region, that of the non-porous region, and their average value can be controlled.

The kind and amount of the urethane-based prepolymer, the curing agent, and the foaming agent are the same as described above with respect to the composition.

The step of preparing a raw material mixture may be carried out by mixing the urethane-based prepolymer with the curing agent, followed by further mixing with the foaming agent, or by mixing the urethane-based prepolymer with the foaming agent, followed by further mixing with the curing agent.

According to an embodiment of the present invention, the raw material mixture may further comprise a surfactant, and the content of a silicon (Si) element in the polishing layer derived from the foaming agent and the surfactant may be 5 ppm to 500 ppm.

As an example of the mixing, the urethane-based prepolymer, the curing agent, and the foaming agent may be put into the mixing process substantially at the same time. If the foaming agent, the surfactant, and the inert gas are further added, they may be put into the mixing process substantially at the same time.

As another example, the urethane-based prepolymer, the foaming agent, and the surfactant may be mixed in advance, and the curing agent, or the curing agent with the inert gas, may be subsequently introduced.

According to an embodiment of the present invention, the modulus of the pore region and that of the non-pore region of the polishing layer, and their average value, can be adjusted with the type and content of each component. In particular, they may vary with the type and content of the urethane-based prepolymer, solid phase foaming agent, gas phase foaming agent, and curing agent.

The mixing initiates the reaction of the urethane-based prepolymer and the curing agent by mixing them and uniformly disperses the solid phase foaming agent and the inert gas in the raw materials. In such event, the reaction rate controlling agent may intervene in the reaction between the urethane-based prepolymer and the curing agent from the beginning of the reaction, to thereby control the reaction rate. Specifically, the mixing may be carried out at a speed of 1,000 rpm to 10,000 rpm or 4,000 rpm to 7,000 rpm. Within the above speed range, the inert gas and the solid phase foaming agent may be uniformly dispersed in the raw materials.

The urethane-based prepolymer and the curing agent may be mixed at a molar equivalent ratio of 1:0.8 to 1:1.2, or a molar equivalent ratio of 1:0.9 to 1:1.1, based on the number of moles of the reactive groups in each molecule. Here, “the number of moles of the reactive groups in each molecule” refers to, for example, the number of moles of the isocyanate group in the urethane-based prepolymer and the number of moles of the reactive groups (e.g., amine group, alcohol group, and the like) in the curing agent. Therefore, the urethane-based prepolymer and the curing agent may be fed at a constant rate during the mixing process by controlling the feeding rate such that the urethane-based prepolymer and the curing agent are fed in amounts per unit time that satisfies the molar equivalent ratio exemplified above.

In addition, the step of preparing the raw material mixture may be carried out under the condition of 50° C. to 150° C. If necessary, it may be carried out under vacuum defoaming conditions.

The step of injecting the raw material mixture into a mold and curing it may be carried out under the temperature condition of 60° C. to 120° C. and the pressure condition of 50 kg/m² to 200 kg/m².

In addition, the above preparation process may further comprise the steps of cutting the surface of a polishing pad thus obtained, machining grooves on the surface thereof, bonding with the lower part, inspection, packaging, and the like. These steps may be carried out in a conventional manner for preparing a polishing pad.

According to the process for preparing a polishing pad, the average value of the modulus of the pore region and that of the non-pore region may be adjusted to 0.5 GPa to 1.6 GPa. In this case, it is possible to improve the scratches and surface defects appearing on the surface of a semiconductor substrate and to further enhance the polishing rate.

[Physical Properties of the Polishing Pad]

The thickness of the polishing pad prepared according to an embodiment may be 0.8 mm to 5.0 mm, 1.0 mm to 4.0 mm, 1.0 mm to 3.0 mm, 1.5 mm to 2.5 mm, 1.7 mm to 2.3 mm., or 2.0 mm to 2.1 mm. Within the above range, the basic physical properties as a polishing pad can be sufficiently exhibited while the particle size variation between the upper and lower portions is minimized.

The specific gravity of the polishing pad may be 0.7 g/cm³ to 0.9 g/cm³ or 0,75 g/cm³ to 0.85 g/cm³.

The surface hardness of the polishing pad at 25° C. may be 45 to 65 Shore D, 48 Shore D to 63 Shore D, 48 Shore D to 60 Shore D, 50 Shore D to 60 Shore D, 52 Shore D to 60 Shore D, 53 Shore D to 59 Shore D, 54 Shore D to less than 58 Shore D, or 55 Shore D to 58 Shore D.

The modulus (or bulk modulus) of the polishing pad may be 80 N/mm² to 130 N/mm², 85 N/mm² to 130 N/mm², 85 N/mm² to 127 N/mm², or 88 N/mm² to 126 N/mm².

According to an embodiment of the present invention, the modulus of the polishing pad may be 85 N/mm² to 130 N/mm², the average value of the modulus of the pore region and that of the non-pore region may be 0.6 GPa to 1.6 GPa, and the absolute value of the difference in modulus between the pore region and the non-pore region may be 0.02 GPa and 0.8 GPa.

In addition, the polishing pad may have the same physical properties and pore characteristics as those of the composition according to the above embodiment upon curing in addition to the physical properties exemplified above.

The elongation of the polishing pad may be 50% to 300%, 80% to 300%, 80% to 250%, 75% to 140%, 75% to 130%, 80% to 140%, or 80% to 130%.

According to the embodiment, the average value of the modulus of the pore region and that of the non-pore region contained in the polishing layer is controlled, whereby it is possible to further enhance the polishing rate and within-wafer non-uniformity for each of oxides and tungsten.

Specifically, the polishing pad may have a polishing rate of 725 Å/minute to 803 Å/minute, specifically 730 Å/minute to 800 Å/minute, more specifically 750 Å/minute to 800 Å/minute for tungsten. It may have a polishing rate of 2,750 Å/minute to 2,958 Å/minute, specifically 2,800 Å/minute to 2,958 Å/minute, more specifically 2,890 Å/minute to 2,960 Å/minute for an oxide. Further, with regard to the within-wafer non-uniformity (WIWNU), which indicates the polishing uniformity in the surface of a semiconductor substrate, it is possible to achieve a within-wafer non-uniformity of less than 10%, 4.5% or less, less than 4.3%, 2% to 4.5%, 2% to 4.3%, or 2% to 3.9%, for tungsten. In addition, it is possible to achieve a within-wafer non-uniformity of 2% to 4.5%, 2% to 4.2%, 2% to 3.9%, or 3% to 3.8%, for an oxide.

In addition, the life span of the polishing pad may be 18 hours to 26 hours, specifically 20 hours to 25 hours, more specifically 22 hours to 24 hours. The life span of the polishing pad is preferably in the above range, which is an appropriate life span. Even if the life span exceeds the above range, it may mean that the extent to which a semiconductor substrate is cut is low; thus, the polishing performance may be adversely affected.

The polishing pad may have grooves on its surface for mechanical polishing. The grooves may have a depth, a width, and a spacing as desired for mechanical polishing, which are not particularly limited.

The polishing pad according to another embodiment may comprise an upper pad and a lower pad, wherein the upper pad may have the same composition and physical properties as those of the polishing pad according to the embodiment.

The lower pad serves to support the upper pad and to absorb and disperse an impact applied to the upper pad. The lower pad may comprise a nonwoven fabric or a suede.

In addition, an adhesive layer may be interposed between the upper pad and the lower pad.

The adhesive layer may comprise a hot melt adhesive. The hot melt adhesive may be at least one selected from the group consisting of a polyurethane resin, a polyester resin, an ethylene-vinyl acetate resin, a polyamide resin, and a polyolefin resin. Specifically, the hot melt adhesive may be at least one selected from the group consisting of a polyurethane resin and a polyester resin.

[Process for Preparing a Semiconductor Device]

The process for preparing a semiconductor device according to an embodiment comprises providing a polishing pad; disposing an object to be polished on the polishing pad; and rotating the object to be polished relative to the polishing pad to polish the object to be polished, wherein the polishing pad comprises a polishing layer comprising a pore region comprising a plurality of pores and a non-pore region devoid of pores, and the average value of the modulus of the pore region and that of the non-pore region according to the following Formula 1 is 0.5 GPa to 1.6 GPa

In the process for preparing a semiconductor device, once the polishing pad according to an embodiment is attached to a platen, a semiconductor substrate (200), for example, a wafer, comprising a layer (210) to be polished is disposed on the polishing layer (100) of the polishing pad as depicted in FIG. 3. In such event, the surface of the semiconductor substrate is in direct contact with the polishing surface of the polishing pad. A polishing slurry may be sprayed on the polishing pad for polishing. Thereafter, the semiconductor substrate and the polishing pad rotate relatively to each other, so that the surface of the semiconductor substrate is polished.

Specifically, FIG. 4 schematically illustrates the process for preparing a semiconductor device according to an embodiment of the present invention. Referring to FIG. 4, once the polishing pad (410) according to an embodiment is attached to a platen (420), a semiconductor substrate (430) is disposed on the polishing pad (410). In such event, the surface of the semiconductor substrate (430) is in direct contact with the polishing surface of the polishing pad (410). A polishing slurry (450) may be sprayed through a nozzle (440) on the polishing pad for polishing. The flow rate of the polishing slurry (450) supplied through the nozzle (440) may be selected according to the purpose within a range of about 10 cm³/minute to about 1,000 cm³/minute. For example, it may be about 50 cm³/minute to about 500 cm³/minute, but it is not limited thereto.

Thereafter, the semiconductor substrate (430) and the polishing pad (410) rotate relatively to each other, so that the surface of the semiconductor substrate (430) is polished. In such event, the rotation direction of the semiconductor substrate (430) and the rotation direction of the polishing pad (410) may be the same direction or opposite directions. The rotation speeds of the semiconductor substrate (430) and the polishing pad (410) may be selected according to the purpose within a range of about 10 rpm to about 500 rpm. For example, it may be about 30 rpm to about 200 rpm, but it is not limited thereto.

The semiconductor substrate (430) mounted on the polishing head (460) is pressed against the polishing surface of the polishing pad (410) at a predetermined load to be in contact therewith, the surface thereof may then be polished. The load applied to the polishing surface of the polishing pad (410) through the surface of the semiconductor substrate (430) by the polishing head (460) may be selected according to the purpose within a range of about 1 gf/cm² to about 1,000 gf/cm². For example, it may be about 10 gf/cm² to about 800 gf/cm², but it is not limited thereto.

In an embodiment, in order to maintain the polishing surface of the polishing pad (410) in a state suitable for polishing, the process for preparing a semiconductor device may further comprise processing the polishing surface of the polishing pad (410) with a conditioner (470) simultaneously with polishing the semiconductor substrate (430).

In the polishing pad according to an embodiment, the average value of the modulus of the pore region and that of the non-pore region is adjusted to 0.5 GPa to 1.6 GPa, whereby it is possible to achieve an excellent life span, to improve the scratches and surface defects appearing on the surface of a semiconductor substrate, and to further enhance the polishing rate. Thus, it is possible to efficiently fabricate a semiconductor device of excellent quality using the polishing pad.

### Embodiments for Carrying out the Invention

### EXAMPLE

Hereinafter, the present invention is explained in detail by the following Examples. However, these examples are set forth to illustrate the present invention, and the scope of the present invention is not limited thereto.

### Example 1

1-1: Preparation of a Urethane-Based Prepolymer

A four-necked flask was charged with toluene diisocyanate (TDI), dicyclohexylmethane diisocyanate (H12MDI), polytetramethylene ether glycol (PTMEG), and diethylene glycol (DEG), followed by reaction thereof at 80° C. for 3 hours, thereby preparing a urethane-based prepolymer having a content of the NCO group of 9.1% by weight.

1-2: Configuration of the Device

In a casting machine equipped with feeding lines for a urethane-based prepolymer, a curing agent, an inert gas, and a reaction rate controlling agent, the urethane-based prepolymer prepared above was charged to the prepolymer tank, and 4,4′-methylenebis(2-chloroaniline) (MOCA) was charged to the curing agent tank. In such case, the curing agent was employed in an amount of 23 parts by weight based on 100 parts by weight of the urethane-based prepolymer. In addition, the solid phase foaming agent (manufacturer: Akzonobel, product name: Expancel 461 DE 20 d70, and average particle diameter: 40 μm) was employed in an amount of 2.5 parts by weight based on 100 parts by weight of the urethane-based prepolyrner.

1-3: Preparation of a Sheet

The urethane-based prepolymer, the curing agent, the solid phase foaming agent, and the reaction rate controlling agent were stirred while they were fed to the mixing head at constant rates through the respective feeding lines. The rotation speed of the mixing head was about 5,000 rpm. In such event, the molar equivalent ratio of the NCO group in the urethane-based prepolymer to the reactive groups in the curing agent was adjusted to 1:1, and the total feed rate was maintained at a rate of 10 kg/minute. In addition, the reaction rate controlling agent was fed in an amount of 0.5 part by weight based on 100 parts by weight of the urethane-based prepolymer.

The mixed raw materials were injected into a mold (having a width of 1,000 mm, a length of 1,000 mm, and a height of 3 mm) and solidified to obtain a sheet. Thereafter, the surface of the sheet was ground using a grinder and then grooved using a tip, to thereby prepare a porous polyurethane polishing pad having an average thickness of 2 mm. Here, the content of a silicon (Si) element in the polishing layer was 300 ppm.

### Examples 2 to 4

A polishing pad was prepared in the same manner as in Example 1, except that the contents of the solid phase foaming agent, the gas phase foaming agent (nitrogen gas (N₂)), the curing agent, and the surfactant (silicone surfactant (manufacturer: Evonik, product name: B8462)), the type of the solid phase foaming agent, and the content of a silicon (Si) element in the polishing layer were adjusted as shown in Table 1 below.

### Example 5

A polishing pad was prepared in the same manner as in Example 1, except that toluene diisocyanate (TDI) alone was used as an isocyanate compound when a urethane-based prepolymer having a content of the NCO group of 9.1% by weight was prepared, nitrogen gas (N₂) as a gas phase foaming agent was constantly fed in a volume of 35% of the total volume of the urethane-based prepolymer, the curing agent, the reaction rate controlling agent, and the silicone surfactant, and the content of a silicon (Si) element in the polishing layer was adjusted as shown in Table 1 below.

### Comparative Examples 1 to 3

A polishing pad was prepared in the same manner as in Example 1, except that the contents of the solid phase foaming agent, the gas phase foaming agent, the curing agent, and the surfactant, the type of the solid phase foaming agent, and the content of a silicon (Si) element in the polishing layer were adjusted as shown in Table 1 below.

### Comparative Example 4

A polishing pad was prepared in the same manner as in Example 1, except that a urethane-based prepolymer having a content of the NCO group of 9.5% by weight was used, the contents of the urethane-based prepolymer, the solid phase foaming agent, the gas phase foaming agent, the curing agent, and the surfactant and the content of a silicon (Si) element in the polishing layer were adjusted as shown in Table 1 below.

Specific process conditions for preparing the upper pad of the polishing pad are summarized in Table 1 below.

TABLE 1

| | | Example | | | | | Comparative Example | | | |
|---|---|---|---|---|---|---|---|---|---|---|
| | | 1 | 2 | 3 | 4 | 5 | 1 | 2 | 3 | 4 |
| Prepolymer | NCO % | 9.1 | 9.1 | 9.1 | 9.1 | 9.1 | 9.1 | 9.1 | 9.1 | 9.5 |
| | Content | 100 | 100 | 100 | 100 | 100 | 100 | 100 | 100 | 100 |
| | (part by weight) | | | | | | | | | |
| Content of the curing agent | | 23 | 23 | 20 | 25 | 23 | 23 | 28 | 17 | 25 |
| (part by weight) | | | | | | | | | | |
| Solid phase | D50 (μm) | 40 | 20 | 40 | 40 | — | 40 | 40 | 40 | 40 |
| foaming agent | Density (kg/m³) | 42 | 70 | 42 | 42 | — | 25 | 42 | 42 | 42 |
| | Content | 2.5 | 1.5 | 1.5 | 1.5 | — | 1.5 | 1.5 | 1.5 | 1.5 |
| | (part by weight) | | | | | | | | | |

| | | | | | | | | | |
|---|---|---|---|---|---|---|---|---|---|
| Content of the surfactant | — | 0.5 | 0.5 | 0.5 | 1 | 0.5 | 0.5 | 0.5 | 0.5 |
| (part by weight) | | | | | | | | | |
| Gas phase foaming agent | — | 27 | 27 | 27 | 35 | 27 | 27 | 27 | 27 |
| (% by volume) | | | | | | | | | |
| Content of silicon (Si) | 300 | 223 | 103 | 165 | 0 | 9,740 | 130 | 276 | 205 |
| (ppm) | | | | | | | | | |

Test Example

The polishing pads obtained in Examples 1 to 5 and Comparative Examples 1 to 4 were tested for the following items.

(1) Surface Hardness

The Shore D hardness was measured. The multilayer polishing pad was cut into a size of 2 cm×2 cm (thickness: 2 mm) and then allowed to stand for 16 hours under the conditions of a temperature of 25° C. and a relative humidity of 50±5%. Thereafter, the hardness of the multilayer polishing pad was measured using a hardness meter (D-type hardness meter).

(2) Specific Gravity

The polishing pad was cut into a rectangle of 4 cm×8.5 cm (thickness: 2 mm) and then allowed to stand for 16 hours under the conditions of a temperature of 23±2° C. and a humidity of 50±5%. The specific gravity of the polishing pad was measured using a gravimeter.

(3) Characteristics of Pores

The pores of the polishing pad were observed with a scanning electron microscope (SEM), and the characteristics of the pores were calculated based on the SEM image. The results are summarized in Table 2 below.

Number average diameter: Average of the sum of the pore diameters divided by the number of pores on the SEM image

Number of pores: Number of pores per 1 mm² on the SEM image

(4) Bulk Modulus

The ultimate strength immediately before the fracture was measured while the polishing pad was tested at a rate of 500 mm/minute using a universal testing machine (UTM).

(5) Modulus of the Pore Region and Modulus of the Non-Pore Region

A force of 100 μN was applied to the pore region and the non-pore region with a nano indenter (TI-950 of Bruker), and the strain versus stress after the force was released were plotted, from which the modulus was calculated as the slope.

(6) Polishing Rates for Tungsten and Oxides

<Polishing Rate for Tungsten>

A silicon wafer having a size of 300 mm with a tungsten (W) layerformed by a CVD process was set in a CMP polishing machine. The silicon wafer was set on the polishing pad mounted on the platen, while the tungsten layer of the silicon wafer faced downward. Thereafter, the tungsten layer was polished under a polishing load of 2.8 psi while the platen was rotated at a speed of 115 rpm for 30 seconds and a colloidal silica slurry was supplied onto the polishing pad at a rate of 190 ml/minute. Upon completion of the polishing, the silicon wafer was detached from the carrier, mounted in a spin dryer, washed with deionized water (DIW), and then dried with air for 15 seconds. The layer thickness of the dried silicon wafer was measured before and after the polishing using a contact type sheet resistance measuring instrument (with a 4-point probe). The polishing rate was calculated using the following Equation 1.

Polishing rate (Å/minute)=difference in thickness before and after polishing (Å)/polishing time (minute) [Equation 1]

<Polishing Rate for an Oxide>

In addition, a silicon wafer having a size of 300 mm with a silicon oxide (SiOx) layer formed by a TEOS-plasma CVD process was used, instead of the silicon wafer with a tungsten layer, in the same device. The silicon wafer was set on the polishing pad mounted on the platen, while the silicon oxide layer of the silicon wafer faced downward. Thereafter, the silicon oxide layer was polished under a polishing load of 1.4 psi while the platen was rotated at a speed of 115 rpm for 60 seconds and a fumed silica slurry was supplied onto the polishing pad at a rate of 190 ml/minute. Upon completion of the polishing, the silicon wafer was detached from the carrier, mounted in a spin dryer, washed with deionized water (DIW), and then dried with air for 15 seconds. The difference in film thickness of the dried silicon wafer before and after the polishing was measured using a spectral reflectometer type thickness measuring instrument (manufacturer: Kyence, model: SI-F80R). Then, the polishing rate was calculated with the above Equation 1.

(7) Within-Wafer Non-Uniformity for Tungsten and Silicon Oxide

The silicon wafers having a tungsten or a silicon oxide (SiOx) layer prepared in the same manner as in Test Example (6) were each coated with 1 μm (10,000 Å) of a thermal oxide layer, which was polished for 1 minute under the conditions as described above. The in-plane film thickness at 98 points of the wafer was measured to calculate the within-wafer non-uniformity (WIWNU) by the following Equation 2:

Polishing within-wafer non-uniformity (WIWNU)(%)=(maximum film thickness−minimum film thickness)/2×average film thickness×100 [Equation 2]

(8) Number of Scratches

After the same CMP process as in Test Example (6) was carried out using the polishing pad, the surface of the wafer was observed using wafer inspection equipment (AIT XP+, KLA Tencor) to measure the number of scratches appearing on the wafer surface upon the polishing (threshold: 150, die filter threshold: 280).

(9) Evaluation of Life Span

The polishing pads prepared in the Examples and the Comparative Examples were each attached to the platen of CMP equipment, and a wafer was not mounted. A CI-45 conditioner of Saesol Diamond was installed, and the conditioner load was adjusted to 6 lbs. The conditioner rotation speed was adjusted to 101 times per minute, and the conditioner sweep speed was adjusted to 19 times per minute. Thereafter, deionized water (DIW) was supplied at a rate of 200 ml/minute, while the platen was rotated at 115 rpm to continuously polish the polishing pad. The depth of the grooves was measured every 1 hour, and the groove consumption rate was calculated using Equation 3 below as a ratio relative to the initial groove depth of the polishing pad. The time when the groove usage rate becomes 55% or more is defined as the life span (hr).

Groove consumption rate(%)=groove depth after polishing(μm)/initial groove depth(μm)×100 [Equation 3]

The results are shown in Tables 2 and 3 below.

TABLE 2

| | Example | | | | | Comparative Example | | | |
|---|---|---|---|---|---|---|---|---|---|
| Properties of the pad | 1 | 2 | 3 | 4 | 5 | 1 | 2 | 3 | 4 |
| Surface hardness (Shore D) | 56.5 | 56.0 | 56.2 | 56.7 | 56.1 | 56.5 | 57.5 | 55.0 | 58.0 |
| Specific gravity (g/ml) | 0.8 | 0.8 | 0.8 | 0.8 | 0.8 | 0.8 | 0.8 | 0.8 | 0.8 |
| Number avg. diameter of the | 24.1 | 16.0 | 24.5 | 24.3 | 26.0 | 24.9 | 24.0 | 24.6 | 23.5 |
| pores (μm) | | | | | | | | | |
| Number of the pores (count/ml) | 1,004 | 1,232 | 1,052 | 1,021 | 856 | 1,100 | 1,003 | 1,028 | 1,108 |
| Bulk modulus (N/mm²) | 120 | 126 | 105 | 125 | 88 | 115 | 160 | 72 | 135 |
| Modulus of the non-pore region (GPa) | 1.12 | 1.08 | 1.20 | 1.07 | 1.15 | 1.14 | 2.10 | 0.49 | 2.77 |
| Modulus of the pore region | 0.98 | 1.13 | 1.15 | 1.60 | 1.01 | 2.24 | 2.01 | 0.41 | 2.53 |
| (GPa) | | | | | | | | | |
| Avg. value of the modulus of | 1.05 | 1.105 | 1.175 | 1.335 | 1.08 | 1.69 | 2.05 | 0.45 | 2.65 |
| the pore region and that of the | | | | | | | | | |
| non-pore region (GPa) | | | | | | | | | |

TABLE 3

| | Example | | | | | Comparative Example | | | |
|---|---|---|---|---|---|---|---|---|---|
| Performance of the pad | 1 | 2 | 3 | 4 | 5 | 1 | 2 | 3 | 4 |
| Polishing rate for oxides | 2,931 | 2,950 | 2,932 | 2,894 | 2,903 | 2,960 | 3,350 | 2,900 | 3,213 |
| (Å/min) | | | | | | | | | |
| WIWNU for oxides (%) | 3.7 | 3.8 | 3.6 | 3.5 | 3.3 | 3.4 | 4.6 | 3.8 | 5.9 |
| Polishing rate for tungsten | 790 | 780 | 795 | 795 | 800 | 805 | 724 | 1,080 | 724 |
| (Å/min) | | | | | | | | | |
| WIWNU for tungsten (%) | 4.2 | 3.5 | 3.6 | 2.9 | 3.9 | 3.8 | 3.5 | 6.9 | 7.5 |
| Number of scratches (count) | <5 | <5 | <5 | <5 | <5 | 45 | 30 | 10 | 15 |
| Life span (hr) | 24 | 24 | 24 | 24 | 24 | 24 | 32 | 16 | 28 |

As can be seen from Tables 2 and 3 above, the polishing pads of Examples 1 to 5 prepared according to an embodiment of the present invention in which the average value of the modulus of the pore region and that of the non-pore region was within the range of 0.5 GPa to 1.6 GPa were excellent in the polishing performance, scratch reduction rate, and life span as compared with the polishing pads of Comparative Examples 1 to 4 in which the average value of the modulus of the pore region and that of the non-pore region fell outside the above range.

Specifically, in terms of the polishing rates of the polishing pads, the polishing pads of Examples 1 to 5 in which the average value of the modulus of the pore region and that of the non-pore region was adjusted within the above range had a polishing rate for an oxide of 2,750 Å/minute to 2,958 Å/minute and that for tungsten of 725 Å/minute to 803 Å/minute and a within-wafer non-uniformity for an oxide and tungsten of 2% to 4.5%, respectively. Thus, it was possible to achieve an appropriate level of polishing rate and within-wafer non-uniformity.

In contrast, in Comparative Examples 1, 2, and 4 in which the average value of the modulus of the pore region and that of the non-pore region exceeded 1.60 GPa, the number of scratches of the polishing pads was significantly increased as compared with that of the polishing pads of Examples 1 to 5, and the polishing rates for oxides and tungsten were excessively increased as well. In addition, in Comparative Example 3 in which the average value of the modulus of the pore region and that of the non-pore region was less than 0.50 GPa, the polishing rate for tungsten was significantly increased as compared with that of the polishing pads of Examples 1 to 5, and the within-wafer non-uniformity for tungsten was deteriorated as well. In addition, in terms of the extent of scratches of the polishing pads, in the polishing pads of Examples 1 to 5, the number of scratches of the wafer was less than 5, which was significantly reduced as compared with 10 to 45 scratches of Comparative Examples 1 to 4. In particular, in Comparative Example 1 in which the content of silicon (Si) in the polishing layer was excessively high as about 9,740 ppm and the absolute value of the difference in modulus between the pore region and the non-pore region exceeded 1 GPa, the number of scratches was 45, which was significantly increased as compared with the polishing pads of Examples 1 to 5. In addition, in Comparative Example 4 in which the NCO % of the urethane-based prepolymer was excessively large as 9.8% by weight, the average value of the modulus of the pore region and that of the non-pore region was excessively increased, so that the polishing rate for oxides was excessively increased, the within-wafer non-uniformity for oxides and tungsten was poor, and the scratches on the surface of a semiconductor substrate was increased.

Meanwhile, in terms of the life span of the polishing pads, the polishing pads of Examples 1 to 5 had an appropriate level of a life span of 24 hours, whereas the polishing pads of Comparative Examples 2 and 4 in which the modulus of the non-pore region and that of the pore region exceeded 2.0 GPa, respectively, the life span of the polishing pads was excessive increased. As a result, the surface of the polishing pad may be glazed, thereby increasing the occurrence of scratches on a wafer.

Reference Numeral of the Drawings

| | |
|---|---|
| 100: polishing layer | |
| 110: non-pore region | 125: pore region |
| 121, 122: open pores | 130: closed pore |
| 200: semiconductor substrate | 210: object to be polished |
| D: average diameter of open pores | |
| H: average depth of open pores | |
| 410: polishing pad | 420: platen |
| 430: semiconductor substrate | 440: nozzle |
| 450: polishing slurry | 460: polishing head |
| 470: conditioner | |

1. A polishing pad, which comprises a polishing layer comprising a pore region comprising a plurality of pores and a non-pore region devoid of pores, wherein an average value of a modulus of the pore region and that of the non-pore region according to the following Formula 1 is 0.5 GPa to 1.6 GPa:
(modulus of the pore region+modulus of the non-pore region)/2. [Equation 1]

2. The polishing pad of claim 1, wherein the modulus of the pore region and that of the non-pore region are 0.5 GPa to 2.0 GPa, respectively.

3. The polishing pad of claim 1, wherein an absolute value of the difference in modulus between the pore region and the non-pore region is less than 1 GPa.

4. The polishing pad of claim 1, wherein the polishing layer comprises a cured material of a composition comprising a urethane-based prepolymer, a curing agent, and a foaming agent, and a content of the curing agent is 18 parts by weight to 27 parts by weight based on 100 parts by weight of the urethane-based prepolymer.

5. The polishing pad of claim 4, wherein the curing agent comprises at least one selected from a group consisting of 4,4′-methylenebis(2-chloroaniline) (MOCA), diethyltoluenediamine (DETDA), diaminodiphenylmethane, diaminodiphenyl sulphone, m-xylylenediamine, isophoronediamine, ethylenediamine, diethylenetriamine, triethylenetetramine, polypropylenediamine, polypropylenetriamine, and bis(4-amino-3-chlorophenyl) methane.

6. The polishing pad of claim 4, wherein a content of a silicon (Si) element in the polishing layer is 5 ppm to 500 ppm.

7. The polishing pad of claim 6, wherein the composition further comprises a surfactant, and the silicon (Si) element is derived from the foaming agent and the surfactant.

8. The polishing pad of claim 4, wherein the urethane-based prepolymer has a content (NCO %) of isocyanate end groups of 8% by weight to 9.4% by weight.

9. The polishing pad of claim 6, wherein a content of the surfactant is 19 parts by weight to 26 parts by weight based on 100 parts by weight of the urethane-based prepolymer,
the content of the silicon (Si) element in the polishing layer is 5 ppm to 400 ppm, and
the urethane-based prepolymer has a content (NCO %) of isocyanate end groups of 9% by weight to 9.4% by weight.

10. The polishing pad of claim 1, which has a modulus of 80 N/mm² to 130 N/mm², a specific gravity of 0.7 g/cm³ to 0.9 g/cm³, and a surface hardness at 25° C. of 45 to 65 shore D.

11. The polishing pad of claim 1, which has a modulus of 85 N/mm² to 130 N/mm², wherein the average value of the modulus of the pore region and that of the non-pore region is 0.6 GPa to 1.6 GPa, and the absolute value of the difference in modulus between the pore region and the non-pore region is 0.02 GPa to 0.8 GPa.

12. The polishing pad of claim 1, wherein a number average diameter of the plurality of pores is 10 μm to 60 μm.

13. The polishing pad of claim 1, wherein the polishing layer has an area ratio of the pore region and the non-pore region per unit area of 1:0.6 to 2.4.

14. The polishing pad of claim 1, which has a polishing rate of 725 Å/minute to 803 Å/minute for tungsten and a polishing rate of 2,750 Å/minute to 2,958 Å/minute for an oxide.

15. The polishing pad of claim 1, which has a within-wafer non-uniformity of 2% to 4.5% for an oxide and tungsten, respectively.

16. A process for preparing a polishing pad, which comprises:
mixing a urethane-based prepolymer, a curing agent, and a foaming agent to prepare a raw material mixture; and
injecting the raw material mixture into a mold to cure the raw material mixture,
wherein the polishing pad comprises a polishing layer comprising a pore region comprising a plurality of pores and a non-pore region devoid of pores, and
an average value of a modulus of the pore region and that of the non-pore region according to the following Formula 1 is 0.5 GPa to 1.6 GPa:
(modulus of the pore region+modulus of the non-pore region)/2 [Equation 1]

17. A process for preparing a semiconductor device, which comprises:
providing a polishing pad;
disposing an object to be polished on the polishing pad; and
rotating the object to be polished relative to the polishing pad to polish the object to be polished,
wherein the polishing pad comprises a polishing layer comprising a pore region comprising a plurality of pores and a non-pore region devoid of pores, and
an average value of a modulus of the pore region and that of the non-pore region according to the following Formula 1 is 0.5 GPa to 1.6 GPa:
(modulus of the pore region+modulus of the non-pore region)/2. [Equation 1]
